(19) United States
(12) Patent Application Publication
(10) Pub. No.: US 2024/0194464 A1
(43) Pub. Date: Jun. 13, 2024

(54) STABLE GROUND ANODE FOR THIN FILM PROCESSING

(71) Applicant: INTEVAC, INC., Santa Clara, CA (US)

(72) Inventors: Samuel D. Harkness, IV, El Cerrito, CA (US); Thomas P. Nolan, Fremont, CA (US); Stephen M. Daly, Los Gatos, CA (US)

(21) Appl. No.: 18/529,106

(22) Filed: Dec. 5, 2023

Related U.S. Application Data
(60) Provisional application No. 63/434,048, filed on Dec. 20, 2022.
(60) Provisional application No. 63/431,999, filed on Dec. 12, 2022.
(60) Provisional application No. 63/431,984, filed on Dec. 12, 2022.
(60) Provisional application No. 63/431,969, filed on Dec. 12, 2022.
(60) Provisional application No. 63/431,621, filed on Dec. 9, 2022.
(60) Provisional application No. 63/431,608, filed on Dec. 9, 2022.

(51) Int. Cl. H01J 37/34

(52) U.S. Cl. CPC H01J 37/3438; H01J 37/3452; H01J 37/3461; H01J 37/3405; H01J 2237/3323

(57) ABSTRACT

An anode for a plasma chamber, having an anode block having a front surface to face a plasma and a rear surface to face away from the plasma; a magnet positioned within the anode block and generating magnetic field lines extending outwardly from the front surface of the anode block; and an electron filter bar spaced apart and extending over the front surface of the anode block and intercepting at least part of the magnetic field lines.

### RELATED CASES

This Application relates to and claims priority benefit from U.S. Provisional Application Ser. No. 63/434,048, filed on Dec. 20, 2022, and from U.S. Provisional Application Ser. No. 63/431,999, filed on Dec. 12, 2022, and from U.S. Provisional Application Ser. No. 63/431,984, filed on Dec. 12, 2022, and from U.S. Provisional Application Ser. No. 63/431,969, filed on Dec. 12, 2022, and from U.S. Provisional Application Ser. No. 63/431,621, filed on Dec. 9, 2022, and from U.S. Provisional Application Ser. No. 63/431,608, filed on Dec. 9, 2022, the disclosures of which are incorporated herein in their entirety.

### BACKGROUND

### 1. Field

This disclosure relates to systems for forming thin-film layers on substrates using plasma enhanced deposition process.

### 2. Related Art

Traditional plasma physical vapor deposition (PVD) chambers decompose precursor gases to thereby ignite and maintain plasma and accelerate particles from the plasma towards a target having a layer of material to be deposited as a desired thin film on a substrate. However, a bi-product of the plasma process includes electrically insulating species, that can cling to various parts of the chamber and form an insulation layer. As such electrically insulating film accumulates on ground surfaces within the process chamber, the anode in the plasma circuit diminishes in viability. As the firm accumulates and the anode is coated with insulation, the plasma becomes less stable and predictable, and leads to some or all of the following: high incidence of arcing, poor film uniformity, and decreased deposition rate. The arcing rate corresponds directly to the amount of particulation that degrades the thin film quality on the substrate and the overall usefulness of the deposition process.

Cathode design for sputtering system has been previously disclosed, which provides enhanced plasma confinement. The reader is directed to, e.g., U.S. Pat. No. 11,456,162, Harkness I V et al., for example of a cathode design. However, in order to provide continuous ground path in a plasma chamber, it would be beneficial to design an anode structure that prevents accumulation of insulation particles thereupon.

### SUMMARY

The following summary of the invention is included in order to provide a basic understanding of some aspects and features of the invention. This summary is not an extensive overview of the invention, and as such it is not intended to particularly identify key or critical elements of the invention, or to delineate the scope of the invention. Its sole purpose is to present some concepts of the invention in a simplified form as a prelude to the more detailed description that is presented below.

Disclosed embodiments provide an anode design that preserves conductive ground surfaces by physically shadowing in such a manner as to inhibit coating species from accumulating, while still remaining available to impacting plasma electrons. According to embodiments, an anode design is disclosed in which attraction of charged species to the uncoated regions is avoided by the incorporation of magnetic field lines that thereby re-direct species off linear trajectories. The magnetic lines further filter electrons from coating material species. This phenomenon may be limited by the spatial area remaining still conductive after coating action. Furthermore, as anode current focuses into these narrow spaces, the amount of resultant Joule heating jeopardizes process stability. If the magnet structure used to generate the anode-going fields increases in temperature, there may be field loss due to the Curie Effect.

Aspects of this disclosure include an anode for a plasma chamber, having an anode block having a front surface to face a plasma and a rear surface to face away from the plasma; a magnet positioned within the anode block and generating magnetic field lines extending outwardly from the front surface of the anode block; and an electron filter bar spaced apart and extending over the front surface of the anode block and intercepting at least part of the magnetic field lines.

Aspect of the disclosure further include an anode for a plasma chamber, the anode incorporating an electron filter having exposed surface facing the plasma region within the plasma chamber and a hidden surface facing away from the plasma region, the electron filter generating a mirroring effect to deflect electrons from the plasma onto the hidden surface. The electron filter preferably maintains magnetic mirror ratio (r=B(max)/B(min), where B is the magnetic field intensity) greater than 10, and more preferably greater than 100. The electron filter may generate the mirroring effect by incorporating a magnet having strength greater than 30 MGOe.

Disclosed embodiments provide an anode for a plasma chamber, comprising an anode block having a front surface facing plasma within the plasma chamber and a back surface facing away from the plasma, the anode block having a cavity open to the back surface; a magnet positioned within the cavity, the magnet being smaller than the cavity such that the magnet does not physically contact any part of the anode block; and at least one filter bar having a free end positioned over and spaced from the front surface, the filter bar having electrical contact to ground potential.

In a related aspect, disclosed embodiments provide a plasma processing chamber comprising: a vacuum enclosure; a cathode having a target of sputtering material mounted thereupon, the cathode positioned within the vacuum enclosure; a gas injector; at least one anode, the anode having an anode block and a magnet positioned within the anode block, the magnet generating magnetic field lines leading from the anode block to the cathode, the anode further comprising a filter bar coupled to ground potential and positioned to intercept part of the magnetic field lines.

Disclosed aspects also provide a plasma processing chamber comprising: a vacuum enclosure; two cathodes positioned within the vacuum enclosure, each cathode having a rotating cylindrical target with coating of sputtering material and a magnetron positioned within the cylindrical target; a gas injector positioned on a ceiling of the vacuum enclosure between the two cathodes; at least one anode attached to sidewall of the vacuum enclosure, the anode having an anode block and a magnet positioned within the anode block, the magnet generating magnetic field lines leading from the anode block to the cathode, the anode further comprising a filter bar forming a peninsular extension attached to the anode block at its isthmus and defining a hollow area between the anode block and the filter bar.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements and are not drawn to scale.

FIG. 1 schematically illustrates a cross-section of a plasma chamber according to disclosed embodiment, while FIG. 1A schematically illustrates a cross-section of an anode incorporated within a gas injector, according to disclosed embodiment;

FIG. 2 schematically illustrates a cross-section of the structure and function of electron filter according to disclosed embodiment;

FIG. 3 schematically illustrates a cross-section of the structure and function of electron filter according to disclosed embodiment;

FIG. 4 schematically illustrates a cross-section of a plasma chamber according to disclosed embodiment.

### DETAILED DESCRIPTION

Embodiments of the inventive anode arrangements will now be described with reference to the drawings. Different embodiments may be used for processing different substrates or to achieve different benefits, such as throughput, film uniformity, target utilization, etc. Depending on the outcome sought to be achieved, different features disclosed herein may be utilized partially or to their fullest, alone or in combination with other features, balancing advantages with requirements and constraints. Therefore, certain features and benefits will be highlighted with reference to different embodiments, but are not limited to the disclosed embodiments, and the features may be incorporated in other embodiments or with other combinations.

Embodiments disclosed herein may be implemented in any plasma-based processing chamber, and are especially suitable for plasma enhanced physical vapor deposition (PVD or sputtering). The embodiments are beneficial for chambers wherein polymers, or other insulative materials, are formed as by products during the plasma process and coat the interior of the chamber. Also, the embodiments are beneficial in chambers wherein an anode forms a pathway for electrons, acting as a ground electrode. When such anodes are coated with the insulative material, the process is degraded due to the disruption of the path to ground. Disclosed embodiments avoid such degradation.

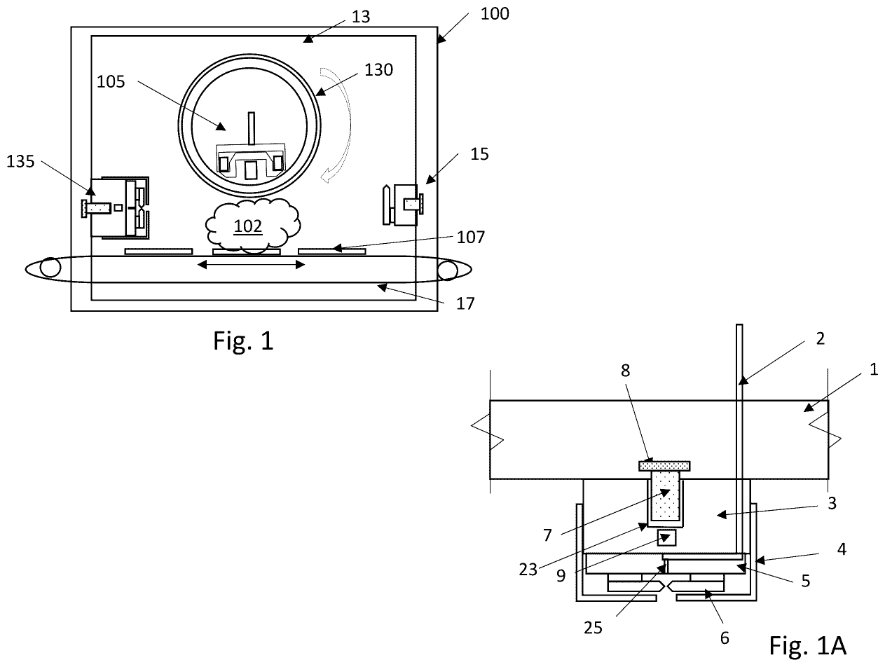

FIG. 1 schematically illustrates a chamber constructed for vacuum processing in the form of physical vapor deposition, having two different anodes according to disclosed embodiments. In this embodiment, a rotating cylindrical sputtering target 130 is situated within the vacuum chamber 100, but other sputtering targets may be utilized, rotating or stationary. Also, generally vacuum chamber 100 may be circular, rectangular, square, etc., while for simplicity the embodiments that utilize a cylindrical target would be considered as being rectangular. A magnetron 105 positioned within target 130 ignites and maintains plasma 102 over a section of the target 130, such that as target 130 rotates, a different surface of the target is bombarded by species from the plasma. Particles from the target 130 are then sputtered off the target and land on the substrate 107 to form a coating. Here, as an example, the substrates travel on a conveyor belt 17, but the substrate may be stationary or in motion, e.g., on a carrier, during the sputtering process.

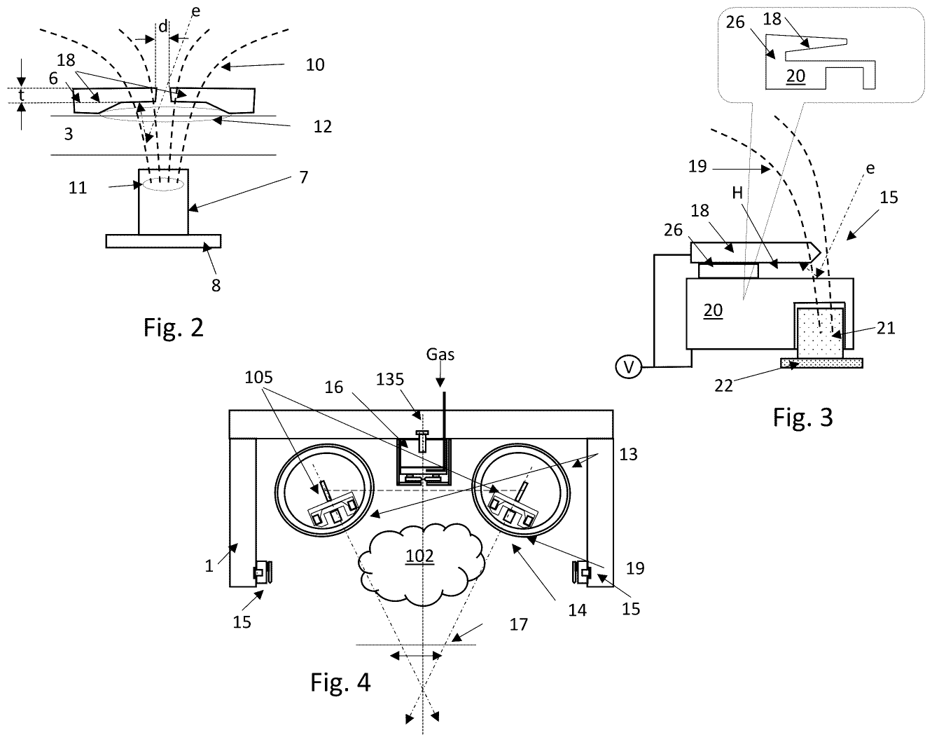

Plasma is ignited and maintained by injecting precursor gas from injector assembly 135, which also acts as anode, as will be explained with reference to FIG. 2. Another anode structure 15 is shown and will be described further with reference to FIG. 3. The flux is generated under classical magnetron dynamics wherein the magnetically confined region defined by the magnetrons 105 enable efficient ionization of gas species such as Ar, Kr, Xe, Ne, He, etc., which subsequently become accelerated toward the cathode held at potential (e.g., −400 V or larger). The impact of these accelerated species imparts sufficient energy to dislodge previously bonded material of the target 130 into the vacuum space where they then become available for deposition on the substrate 107. The targets 130 are made of material that ultimately deposit on the intended substrate 107 with identical stoichiometry. Conversely, the injector assembly 135 may additionally injects reactive gas, such oxygen and/or nitrogen, which would react with the sputtered species, so that the layer formed on the substrates 107 incorporates reacted species.

A typical use of the above-mentioned setup is to convert a material from the target's stoichiometry to a film comprising an adjusted oxidation state (compared to the original material). Such films generally become dielectric and often present opportunities in the fields of optics, tribology and diffusion to name a few. The most common practice involves introduction of reactive gases (e.g., O, N, H, etc.) during processing that ultimately form the desired bonding and resultant stoichiometry in the film, e.g., SiAlON. This process will often produce an excessive amount of electrons that may cause deleterious plasma damage and heating effects and thereby inhibit film quality. One remedy utilizes an engineered anode to collect the excessive flux and thereby remove it from possible film interaction. However, the adsorbate typically insulates all surfaces on the interior of the chamber and the anode is no exception. Therefore, the plasma tends to become unstable as the anode “disappears”, i.e., it's electrical potential with respect to the plasma is insulated by oxidation material build-up so that from the perspective of charged particles within the plasma, it doesn't exist.

FIG. 1A is a schematic showing the features comprising the novel approach to a centralized anode incorporated within the gas injection assembly 135. It should be noted that while in FIG. 1 the gas injection assembly 135 is shown on one sidewall of the chamber, it may actually be placed anywhere that is appropriate for gas injection, e.g., on the ceiling, as shown in FIG. 4. Also, when deployed between two cylindrical rotating targets as shown in FIG. 4, the elements of the centralized anode of FIG. 1A (e.g., anode block 3, magnet array 7, keeper plate 8, gas distribution plate 5, and filters 6) may extend to the length of the cylindrical target (i.e., into the paper as shown in FIG. 1A).

As shown in FIG. 1A, an anode block 3 is affixed to the chamber wall 1 (or to the ceiling, FIG. 3). The anode block 3 is most appropriately metallic, e.g., aluminum or copper, or otherwise conductive material (both electrical and thermal conductivity). A magnet 7 is mounted on a keeper plate 8, which also affixes directly to the chamber wall 3 and extends into a cavity 23 within anode block 3, such that when at vacuum, there is no connective material making lateral electrical or thermal connection from the magnet 7 directly to the anode block 3. This design criteria is beneficial to inhibiting current flow directly through the magnet structure and preserves thermal stability of the magnet.

Cooling channels 9 are cut into the anode block 3 to allow coolant flow therein to control the temperature of the anode block 3. Additionally, gas delivery line 2 passes through the anode block and provides gas to at least one gas injection orifice 25. The one or more gas injection orifices are provided on a gas distribution plate 5 (also conductive material) that is attached to the top of the anode block 3 and is connected to the gas delivery line 2 to facilitate gas orifice 25 delivery of prescribed gas species to the vacuum environment. Drilled orifices of gas injector 25 are less than 2 mm and more preferably below 1.6 mm in diameter. Such specifications inhibit plasma formation within the plate 5 regardless of the possible electrical potential (as per Paschen's Law). Consequently, less secondary electron generation and consequently lower plasma density forms in the region surrounding the orifice. Also, the at least one orifice is collinear with the highest density of magnet field lines from the magnet 7.

FIG. 2 demonstrates the spatial relationship for the structure of electron filter 6. This filter 6 consists of two filter bars 18 facing each other with a gap therebetween, marked as d. The filter 6 features dimensions that promote the separation of electrons following magnetic field lines from adsorbate particles following line-of-sight trajectories. Specifically, the overall thickness t of the free-standing end of the filter bar is larger, and preferably twice as thick as the distance d separating nearest edge of the mirroring filter bars 18 across the centerline of the anode structure. In embodiments the thickness t is greater than 3 millimeters and may even be greater than 5 millimeters. This collimation optimizes the competing effects of filtering and total capture of electrons. Also, the free-standing end of the filter bar is beneficially thinner than the opposite end that is attached to the anode block, thus defining a hollow area between the anode block and the filter bars.

FIG. 2 illustrates the electron mirroring benefit to ground capture. Magnetic field lines (dashed curves) 10 connect cathode arrays to the center of the anode. A region 11 (dotted oval) shows the densification of field lines as they approach the anode magnet 7. The increase in field intensity, B, causes the reflection of inbound electrons e. The likelihood of momentum transfer causes the electron to reverse course at an angle to the incidence, see dash-dot arrow marked e. As such the collection of reflected trajectories forms a loss cone that is wider than the aperture that admitted the electrons into the anode filter structure. This is represented as dotted oval 12 in FIG. 2, within the hollow space defined between the anode block 3 (or the gas distribution plate 5 if used) and the filter bars 6. The loss reflection allows electrons to then impact on fresh conductive interior surfaces of the filter bars 6, that provide ultimately a pathway to ground. In this way, the anode is kept viable regardless of coating action in the body of the chamber. That is, even if the front surface (i.e., plasma facing surface) of filter 6 gets coated with insulative material, the interior surface (i.e., surfaces hidden from the plasma) would remain exposed and therefore viable conductive pathway to ground.

Reverting to FIG. 1A, this set of phenomena reduces the chance for insulating material such as oxides or nitrides to form atop the conductive metal surface of plate 5 or other local structures, such as the electron filter 6. This optimizes the anode structure for durable performance over extended campaign times. To facilitate the rigors of manufacturing, a consumable or sacrificial shield 4 attaches to the outer portion of the anode block 3, where accumulated material clings to further protect the anode from deposition of insulative material.

Another embodiment of an anode 15 is shown positioned on the sidewall of the chamber, peripherally of the cathodes 13 and detailed in FIG. 3. A peripheral anode block 20 is attached to the chamber wall 100. Instead of a dual filter structure as shown in FIGS. 1 and 1A, only half such an assembly is required since only one cathode's field lines 19 are connecting to the peripheral anode 15. Filter bar 18 is attached to the anode block 20, set off by spacer 26, to thereby form a peninsula connected to the anode block at its isthmus, and defining hollowed area H between the filter bar 18 and the anode block 20. In this respect, it can be said that the filter bar 18 is cantilevered off of spacer 26. Also, as illustrated in the callout, in any of the disclose embodiments, the anode block 20, spacer 26 and filter bar 18 may be made integrally as a single block having the cavity for the magnet in the rear and the cantilevered filter bar in the front. In any of the disclosed embodiments the free end of the filter bar 18 may be thinner than the attachment end which is attached to the anode block, or the entire filter bar 18 may be tapered towards its free end, as shown in the callout.

Magnet 21 is inserted into cavity in the anode block and is attached to keeper plate 22, wherein no part of the magnet 21 or keeper plate 22 physically contacts the anode block 20, such that a vacuum break is formed between the magnet 21 and keeper plate 22 and the anode block 20. The filter bar 18 is positioned so as to partially cross the magnetic lines emanating from magnet 21, so that some of the magnetic field lines cross the filter bar 18 and some field lines do not cross filter bar 18. Consequently, electrons deflected by the magnetic field would impact the interior surface of the filter bar 18 that faces away from the plasma, and thus remains uncoated by insulating species.

In any of the disclosed embodiments, the anode block may be electrically connected to the chamber body and be at the same potential as the chamber body, e.g., ground potential. Conversely, as exemplified in FIG. 3, the anode block may be insulated from the chamber body and be connected individually to a potential source, or the filter bar may be connected to the potential source. Also, in any of the disclosed embodiments, the magnet has a strength greater than 30 MGOe (mega-gauss-oersted). In any of the disclosed embodiments, the magnetic mirror ratio (r=B(max)/B(min), where B is the magnetic field intensity) is greater than 10 and more preferably greater than 100. In this respect, magnetic mirror refers to the configuration of magnets within the anodes and cathodes to create an area with an increasing density of magnetic field lines at either end of a confinement volume. In the disclosed embodiments the end of interest is at the anode. Particles approaching the ends experience an increasing force that eventually causes them to reverse direction and return to the confinement area. This mirror effect will occur only for particles within a limited range of velocities and angles of approach, while those outside the limits will escape. In the context of the disclosed embodiments, electrons would be deflected to reverse direction and hit the interior side of the electron filter, which is not exposed to insulative coating, thus ensuring clear path to ground for removal of electrons from the plasma.

FIG. 4 schematically illustrates an embodiment utilizing two rotating cylindrical targets. This embodiment employs dual cylindrical magnetron sputtering arrangement and, more specifically, reactive processing deployed with sufficient symmetry to facilitate pass-by or inline film deposition. In FIG. 4, a cross-sectional schematic drawing shows relative positioning of the two cathodes 13, central gas injection assembly 135 incorporating a central anode 16, and two opposing anodes 15. As illustrated, the two magnetrons 105 within the cylindrical targets are tilted towards one another, such that plasma 102 is maintained between the two cathodes 13. Each of the magnetrons defines an axis of symmetry that passes through its center, represented in FIG. 4 by the dash-dot arrows. The axes of symmetry of the two magnetrons cross each other at a point ahead of the surfaces of the rotating targets. When the two rotating targets are positioned horizontally, i.e., a straight line passing through their axis of rotation is horizontal line (see wide-dash line), the two axes of symmetry cross each other at a crossing point below the horizontal line. Additionally, a straight line connecting the crossing point and the center of gas injection assembly 135 is perpendicular to the horizontal line (see dotted line in FIG. 4).

With this orientation, the two cathodes 13 impose a flux of adsorbate material upon a substrate 17 positioned on a tray or carrier, which is either stationary or continuously moving at a prescribed velocity (e.g., 1-300 mm/s). In this embodiment, the gas injection assembly 135 incorporating anode 16 is situates on the ceiling of the chamber, at a point midway between the twin cathodes 13, such that the gas injected from the gas injection assembly 135 flows to an area between the targets to maintain plasma between the targets. With this orientation of rotating targets, central gas injection, and symmetrical anodes, a stable process with controllable flow of charge ensues. An important aspect of the above design is further described regarding the confinement of cathode plasma. To ensure that a predominant proportion of the ground-going electron flow proceeds into the designed anode structure, magnetic confinement is required to prevent divergent flow away from such structures. The confinement can be parameterized by analysis of the corresponding current (I) vs. voltage (V) curves. In short, when a plasma is well confined, it takes less voltage to drive the electrons from the cathode to the anode. Therefore, it is necessarily found that the I-V curve slope is a credible statistic to analyze the confinement. Consequently, it is found that a slope of log(I) vs. log(V) greater than at least 3, and more preferable, greater than 4 adequately characterizes a well confined plasma.

In FIG. 4 the gas injection assembly 135 incorporates an anode. In addition, two anodes 15 are positioned on the sidewall opposing each other, such that the magnetic field lines of each anode 15 lead to the corresponding one of cathodes 13. Each of anodes 15 is structured according to embodiments disclosed herein, e.g., see FIG. 3 and its description, wherein the magnetic field lines are partially intercepted by a tapered, free standing edge of filter bar 18.

The disclosed embodiments provide a deposition system comprising: a vacuum enclosure having sidewalls and ceiling, two sputtering targets positioned inside the vacuum enclosure and defining a plasma area therebetween, each of the sputtering targets having a front surface coated with sputtering material and a back surface, the front surface facing the plasma area; two magnetrons, each positioned behind the back surface of a corresponding one of the two targets; a gas injector mounted onto the ceiling and positioned centrally between the two targets; and a central anode mounted onto the ceiling and positioned centrally between the two targets, the central anode having an anode block and a magnet positioned within the anode block; wherein the two targets, the two magnetrons, and the anode confine plasma within the plasma area to have a slope of log(I) vs. log(V) greater than at least 3 or greater than 4. In embodiments the deposition system further comprises two peripheral anodes, each mounted onto the sidewall and positioned next to a corresponding one of the two targets, each of the peripheral anode comprising an anode block having a cavity, a magnet positioned within the cavity and generating magnetic field lines, and a cantilevered filter bar intercepting at least partially the magnetic field lines.

Also disclosed is a plasma chamber comprising a vacuum enclosure housing a target having a front surface facing a plasma region within the vacuum enclosure and a rear surface facing away from the plasma region, the front surface being coated with sputtering material; a magnetron positioned behind the rear surface igniting the plasma and confining the plasma to the plasma region; an anode position inside the vacuum enclosure and incorporating an electron filter having exposed surface facing the plasma region and a hidden surface facing away from the plasma region, the electron filter generating a mirroring effect to deflect electrons onto the hidden surface. In embodiments, the electron filter maintains magnetic mirror ratio (r=B(max)/B(min), where B is the magnetic field intensity) greater than 10, and more preferably greater than 100. In embodiments, the electron filter incorporates a magnet having strength greater than 30 MGOe. In embodiments, the target is shaped as elongated cylinder and the filter extends to the length of the target, wherein the magnet is formed as an array of magnets extending the length of the target.

While the disclosed embodiments are described in specific terms, other embodiments encompassing principles of the invention are also possible. Further, operations may be set forth in a particular order. The order, however, is but one example of the way that operations may be provided. Operations may be rearranged, modified, or eliminated in any particular implementation while still conforming to aspects of the invention.

All directional references (e.g., upper, lower, upward, downward, left, right, leftward, rightward, top, bottom, above, below, etc. are only used for identification purposes to aid the reader's understanding of the embodiments of the present invention, and do not create limitations, particularly as to the position, orientation, or use of the invention unless specifically set forth in the claims. Joinder references (e.g., attached, coupled, connected, and the like) are to be construed broadly and may include intermediate members between a connection of elements and relative movement between elements. As such, joinder references do not necessarily infer that two elements are directly connected and in fixed relation to each other.

In some instances, components are described with reference to “ends” having a particular characteristic and/or being connected to another part. However, those skilled in the art will recognize that the present invention is not limited to components which terminate immediately beyond their points of connection with other parts. Thus, the term “end” should be interpreted broadly, in a manner that includes areas adjacent, rearward, forward of, or otherwise near the terminus of a particular element, link, component, member or the like. It is intended that all matter contained in the above description or shown in the accompanying drawings shall be interpreted as illustrative only and not limiting. Changes in detail or structure may be made without departing from the spirit of the invention as defined in the appended claims.

It must be noted that as used herein and in the appended claims, the singular forms “a”, “an”, and “the” include plural referents unless the context clearly dictates otherwise.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention.

What is claimed is:

1. An anode for a plasma chamber, comprising:
an anode block having a front surface to face a plasma and a rear surface to face away from the plasma;
a magnet positioned within the anode block and generating magnetic field lines extending outwardly from the front surface of the anode block;
an electron filter bar spaced apart and extending over the front surface of the anode block and intercepting at least part of the magnetic field lines.

2. The anode of claim 1, wherein the magnet strength is greater than 30 mega-gauss-oersted.

3. The anode of claim 1, wherein the magnet is inserted within a cavity formed in the anode block, the cavity being larger than the magnet, such that no part of the magnet physically contacts any part of the anode block.

4. The anode of claim 3, further comprising a keeper bar attached to the magnet.

5. The anode of claim 1, wherein the anode block includes cooling channels configured for cooling fluid flow.

6. The anode of claim 1, wherein the anode block and the electron filter bar are formed integrally as one piece of conductive material.

7. The anode of claim 1, wherein the anode block and the electron filter bar are made of copper or aluminum.

8. The anode of claim 1, further comprising a spacer and wherein the electron filter bar is attached at one end to anode block via the spacer.

9. The anode of claim 1, wherein the electron filter bar forms a cantilever having a free end and an attachment end, and wherein the free end is thinner than the attachment end.

10. The anode of claim 1, wherein magnetic mirror ratio of the magnet (r=B(max)/B(min), where B is magnetic field intensity) is greater than 10.

11. The anode of claim 10, wherein the magnetic mirror ratio is greater than 100.

12. The anode of claim 1, further comprising a second filter bar spaced apart and extending over the front surface of the anode block and oriented to mirror the orientation of the electron filter bar and defining a gap between the electron filter bar and the second filter bar.

13. The anode of claim 12, wherein the gap is smaller than thickness of free end of the electron filter bar.

14. The anode of claim 12, wherein the thickness of free end of the electron filter bar is greater than 5 millimeters.

15. The anode of claim 12, further comprising a sacrificial shield attached to the anode block and covering the electron filter bar and the second filter bar.

16. The anode of claim 12, further comprising a gas injection plate attached to the front surface and having at least one orifice for gas injection.

17. The anode of claim 16, wherein the at least one orifice is positioned to inject gas into a space defined by the gas injection plate, the electron filter bar and the second filter bar.

18. The anode of claim 17, wherein the electron filter bar and the second filter bar are attached to the gas injection plate.

19. The anode of claim 17, wherein the electron filter bar and the second filter bar are coupled to ground potential.

20. The anode of claim 17, wherein the electron filter bar and the second filter bar are electrically coupled to the ceiling.

21. The anode of claim 16, wherein the at least one orifice is collinear with highest density of magnet field lines from the magnet.
